(19) United States
(12) Patent Application Publication
(10) Pub. No.: US 2011/0068809 A1
(43) Pub. Date: Mar. 24, 2011

(54) SYSTEM AND METHOD FOR DETERMINING MOISTURE CONTENT IN A BALE OF HAY

(75) Inventors: James Falbo, STOW, OH (US); Trent McElhaney, North Jackson, OH (US)

(73) Assignee: RAINMAKER HOLDING COMPANY, Streetsboro, OH (US)

(21) Appl. No.: 12/562,652

(22) Filed: Sep. 18, 2009

(51) Int. Cl. G01R 27/26

(52) U.S. Cl. 324/664

(57) ABSTRACT

A system for measuring the moisture content in a bale of hay is provided. An embodiment of the system includes a first pair of electrodes configured to mount in a first position in a bale chamber and at least one additional electrode configured to mount in a second position in the bale chamber. The system also includes a controller having circuitry to obtain a first measurement between the first pair of electrodes while the electrodes are in contact with a bale of hay, and a second measurement between at least one of the first pair of electrodes and the at least one additional electrode while the electrodes are in contact with the bale of hay. The controller includes circuitry to output a signal indicative of the moisture content of the bale of hay as a function of the first and second measurements.

### FIELD

Embodiments of the present invention relate generally to moisture detectors for hay balers and methods of determining the moisture content of bales of hay.

### BACKGROUND

Bales of hay are commonly prepared by cutting a crop, such as alfalfa, timothy, clover, etc. near the ground and allowing it to dry. The dried hay is raked into rows and bailed using a hay baler. The bales of hay may be small square bales, large square bales or round bales. Irrespective of what type of hay bale is being produced, it is important to know the moisture content of the hay during the baling process. Too high of a moisture content and the bale will mold, or worse spontaneously combust. Too low of a moisture content may cause loss of nutritional content.

Electric moisture testers for use with hay balers are known. One type of moisture detector employs a sensor having two electrodes mounted in close proximity to one another in the bale chamber. When a bale of hay is in contact with the electrodes a resistance measurement through the hay is measured, and converted into a moisture content of the hay bale. This type of sensor measures resistance across a small area on one end of the bale of hay. Another type of sensor for a moisture detector is described in U.S. Pat. No. 6,377,058. This sensor has two electrodes that are star shaped wheels spaced apart from one another. The star shaped wheels have points that penetrate the hay bale and a resistance measurement is taken across a portion of the bale of hay.

### SUMMARY

Systems for measuring the moisture content in a bale of hay are provided. An embodiment of the system includes a first pair of electrodes configured to mount in a first position in a bale chamber and at least one additional electrode configured to mount in a second position in the bale chamber. The system also includes a controller having circuitry to obtain a first measurement between the first pair of electrodes while the electrodes are in contact with a bale of hay, and a second measurement between at least one of the first pair of electrodes and the at least one additional electrode while the electrodes are in contact with the bale of hay. The controller includes circuitry to output a signal indicative of the moisture content of the bale of hay as a function of the first and second measurements. The controller may have a display for displaying the moisture content, and/or circuitry for communicating the signal indicative of the moisture content to a remote receiver located on a tractor for display on a monitor.

Methods for determining the moisture content of a bale of hay are also provided. One embodiment includes taking a first measurement between a first pair of electrodes while the electrodes are in contact with a side of a bale of hay and taking a second measurement between at least one of the first pair of electrodes and at least one additional electrode, wherein the first pair of electrodes and the at least one additional electrode are positioned so that a signal passing between them travels through at least substantially the width of the bale of hay. The method further comprises providing an output indicative of the moisture content of the bale of hay as a function of the first measurement and the second measurement.

In addition, a method for use of a moisture testing device for use on multiple types of hay balers is provided. An embodiment includes providing a moisture testing device, providing a data set for each type of hay baler that may be selected and having an input for selecting a type of hay baler that is to be used. In one embodiment, the method further includes taking a measurement between a first set of electrodes while the electrodes are in contact with a bale of hay and providing an output indicative of the moisture content of the bale of hay as a function of the measurement and the data set for the selected type of hay bale.

These and other features and a more thorough understanding of the invention may be achieved by referring to the following description, taken in conjunction with the drawings.

### BRIEF DESCRIPTION OF THE DRAWINGS

FIG. 1 is an exemplary block diagram of system for determining moisture content in a hay bale;

FIG. 2 is an exemplary diagram of a sensor for the system for determining moisture content in a hay bale;

FIG. 3 is an exemplary top view of a controller for a system for determining moisture content in a hay bale;

FIG. 4 is an exemplary electrical block diagram of a system for determining moisture content in a hay bale;

FIG. 5 is an exemplary flow chart of a logic diagram in accordance with one embodiment of a method for determining the moisture content of a hay bale;

FIG. 5A is an is an exemplary flow chart of a logic diagram in accordance with one embodiment of a method for determining the moisture content of a hay bale; and

FIG. 6 is an exemplary flow chart of a logic diagram in accordance with one embodiment of a method for using a single controller to determine the moisture content of different types of hay bales.

### DETAILED DESCRIPTION

The following includes definitions of exemplary terms used throughout the disclosure. Both singular and plural forms of all terms fall within each meaning. Except where noted otherwise, capitalized and non-capitalized forms of all terms fall within each meaning:

“Circuit communication” as used herein indicates a communicative relationship between devices. Direct electrical, electromagnetic, and optical connections and indirect electrical, electromagnetic, and optical connections are examples of circuit communication. Two devices are in circuit communication if a signal from one is received by the other, regardless of whether the signal is modified by some other device. For example, two devices separated by one or more of the following—amplifiers, filters, transformers, optoisolators, digital or analog buffers, analog integrators, other electronic circuitry, fiber optic transceivers, or even satellites—are in circuit communication if a signal from one is communicated to the other, even though the signal is modified by the intermediate device(s). As another example, an electromagnetic sensor is in circuit communication with a signal if it receives electromagnetic radiation from the signal. As a final example, two devices not directly connected to each other, but both capable of interfacing with a third device, for example, a CPU, are in circuit communication. Also, as used herein, voltages and values representing digitized voltages are considered to be equivalent for the purposes of this application and thus the term “voltage” as used herein refers to either a signal, or a value in a processor representing a signal, or a value in a processor determined from a value representing a signal.

“Signal” as used herein includes, but is not limited to one or more electrical signals, analog or digital signals, one or more computer instructions, a bit or bit stream, or the like.

“Logic” is synonymous with “circuit” as used herein and includes, but is not limited to hardware, firmware, software and/or combinations of each to perform a function(s) or an action(s). For example, based on a desired application or needs, logic may include a software controlled microprocessor or microcontroller, discreet logic, such as an application specific integrated circuit (ASIC), or other programmed logic device. Logic may also be fully embodied as software. The circuits identified and described herein may have many different configurations to perform the desired functions.

The values identified in the detailed description are exemplary and they are determined as needed for a particular moisture detector system design. Accordingly, the inventive concepts disclosed and claimed herein are not limited to the particular values or ranges of values used to describe the embodiments disclosed herein.

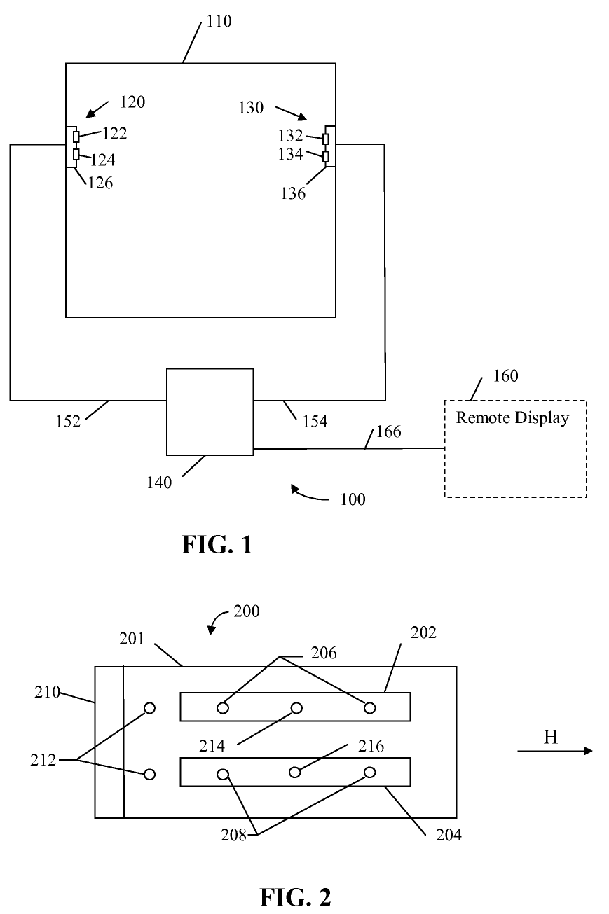

FIG. 1 is a simplified exemplary block diagram of an embodiment of a system 100 for determining the moisture content of a bale of hay in a bale chamber 110. The system 100 includes two sensors 120, 130, a controller 140 and a remote display 160. The first sensor 120 includes a pair of electrodes 122, 124 secured to a non-conductive mounting bracket 126. Similarly, second sensor 130 includes a pair of electrodes 132, 134 secured to a non-conductive mounting bracket 136. Although the embodiments described herein utilize a pair of electrodes at each sensor, the use of one pair of electrodes at one sensor 120 and one additional electrode at the other sensor 130 remote from the first sensor 120 is also contemplated and is within the scope of the inventions described herein. Bale chamber 110 may be a round bale chamber, a small square bale chamber, a large square bale chamber, or any other chamber intended for the use of hay bales.

Sensors 120, 130 are mounted in the inside of a bale chamber 110 of a hay baler (not shown), and preferably mounted on opposite walls of the bale chamber 110. However, sensors 120, 130 may be mounted on the same wall or adjacent walls of the bale chamber 110. The first sensor 120 is in circuit communication with the controller 140 through cable 152. The second sensor 130 is in circuit communication with the controller 140 through cable 154. Controller 140 is in circuit communication with remote display 160 through cable 166. Optionally, one or more of the cables 152, 154, or 166 may be replaced by a wireless connection (not shown). Still yet, in one embodiment, a display may be located on the controller 140 (not shown).

Generally in operation in one embodiment, as a bale of hay passes through the bale chamber 110, controller 140 may take a first measurement between electrodes 122 and 124, a second measurement between electrodes 132 and 134, and a third measurement between electrodes 122 and 132. The controller 140 may utilize the data from the first, second and third measurements to determine the moisture content of the bale of hay. Then the controller 140 communicates a signal indicative of the moisture content of the hay bale to a display, such as a remote display 160 through cable 166 where it is displayed to an operator. Cable 166 may be a proprietary bus, an ISO CAN bus, or other standard protocol bus. A more detailed description of the operation is provided below.

FIG. 2 is an embodiment of a sensor 200 for use in a system for measuring the moisture content of a hay bale. The sensor includes a non-conductive bracket 201, which has a sloped or angled leading surface 210, which slopes toward the surface of a bale chamber. The sloped surface 210 is positioned toward the incoming hay (not shown) so that the compacted hay rides over top of the sensor 200. Thus, baled hay moves in the direction H shown by the arrow in FIG. 2. Mounting holes 212 on the leading edge of the mounting bracket 200 help prevent hay from getting between the sensor 200 and the bale chamber wall (not shown) and shearing the sensor off of the bale chamber wall. Sensor 200 includes two electrodes 202, 204, which are preferably elongated to provide a larger surface area for contacting the hay. Electrodes 202, 204 are preferably spaced about an inch apart. In one embodiment, mounting bracket 201 is extruded from a high density plastic and has slots machined in it to receive electrodes 202, 204. Electrodes 202, 204 are secured to the mounting bracket 201 by conventional means through mounting holes 206, 208. Electrodes 202, 204 and mounting bracket 201 may have holes 214, 216 through them for receiving bolts (not shown). The bolts extend through the wall of the bale chamber and have an isolating sleeve or collar (not shown) around them to electrically isolate the bolt from the wall of the bale chamber. The bolts provide a means for making electrical connections on the outside of the bale chamber to the electrodes located on the inside of the bale chamber.

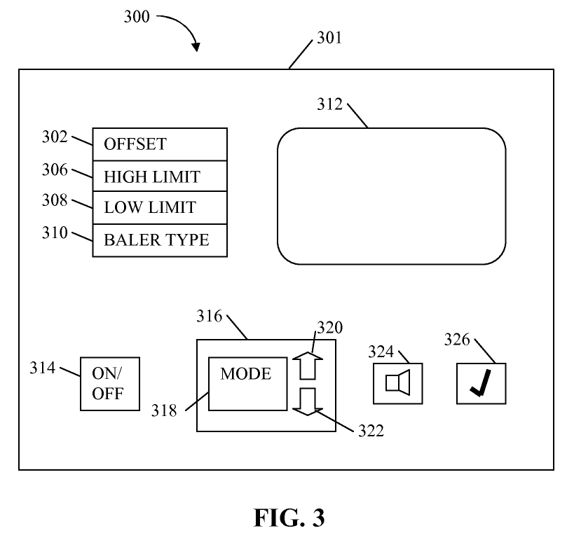

FIG. 3 illustrates a controller 300 in accordance with one embodiment of the present invention. Controller 300 has a housing 301 including a display 312, an on/off button 314, a mute button 324, an internal calibration button 326, and a user interface 316. The user interface 316 includes a mode button 318 and two arrow keys 320, 322. In operation, a user may turn the controller 300 on by pushing the on/off button 314. The user may push the mode button 318 to enter a programming mode. The user presses the up key 320 and the down key 322 to scroll through options that may be changed. Those options may include offset 302, high limit 306, low limit 308 and baler type 310.

The user may enter the programming mode by pushing mode 318, scrolling to baler type 310, and pushing the mode button 318 to select baler type 310. Then the user presses the up key 320 or the down key 322 to select a baler type, for example, a small square baler, a large square baler, or a round baler. Once the correct type of hay baler is highlighted, the user pushes the mode button 318 to select the type of hay baler.

The high limit 306 is used to trigger an alarm if the moisture content is above a set limit. If the user wants to change the high limit 306, the user pushes the mode key 318 and scrolls to the high limit using either the up key 320 or the down key 322. Once the high limit 306 is highlighted, the user pushes the mode button 318 to select high limit 306 and sets the high limit 306 by using the up key 320 or down key 322 and pushing the mode button 318 when the desired limit is highlighted. The newly set high limit 306 is the maximum moisture content desired. During operation if the moisture content of the bale of hay exceeds the high limit 306, an alarm will sound. The alarm may be muted by pushing the mute button 324. In addition, a user may set the low limit 308 in the same way described for the high limit 306. The low limit 308 may be used to alert the user if there is not enough moisture in the bale of hay.

The calibrate button 326 may be used to calibrate the controller 300. The user simply pushes the calibrate button 326 and the controller 300 calibrates itself by applying a known load (not shown) across one of the sensor inputs.

Finally, the user may set the offset 302 by the procedures identified above for setting the high limit 306 and the low limit 308. The offset 302 may be used to offset the moisture readings based on the actual deviation from a true moisture content. For example, if the controller 300 displays a moisture content of 18% on display 312 and the user tests a core sample of the bale of hay and determines that the actual moisture content is 17%, the user may use the offset 302 to subtract 1% from future moisture readings on the display 312.

In another embodiment, controller 300 enters its operational mode upon start up. If a user presses the mode 318 button, controller 300 enters the programming mode and display 312 displays an arrow identifying which programming mode is active. Pressing mode 318 multiple times scrolls through the available programmable options. For example, pressing mode 318 once causes offset 302 to be identified and active so that the offset may be programmed. Pressing mode 318 a second time causes high limit 306 to be active, pressing mode 318 a third time causes low limit 308 to be active and pressing mode 318 a fourth time causes baler type 310 to be active. When a particular programming mode is active, the user may use the up key 320 or down key 322 to program a new setting. After selecting the desired setting the user simply waits a predetermined time and then controller 301 automatically saves any changes made and reverts to its operational mode.

Optional inputs (not shown) may include an input for selecting the width of a bale of hay that is to be produced by the hay bailer. For example, round balers may produce different widths of hay bales, such as for example, a width of 4 feet, 4.5 feet, 5 feet, 5.5 feet, etc. Selecting the width of the hay bale may be used to provide a more accurate moisture content. In addition, other inputs (not shown) may include, for example, a “density” input that allows a user to select the density of the hay bale being produced, which may be used to increase the accuracy of the moisture content output. The user may select a width or density by using the mode button 318 as described above. The widths and densities may be pre-stored values, or the user may use the up key 320 and down key 322 to manually set the values.

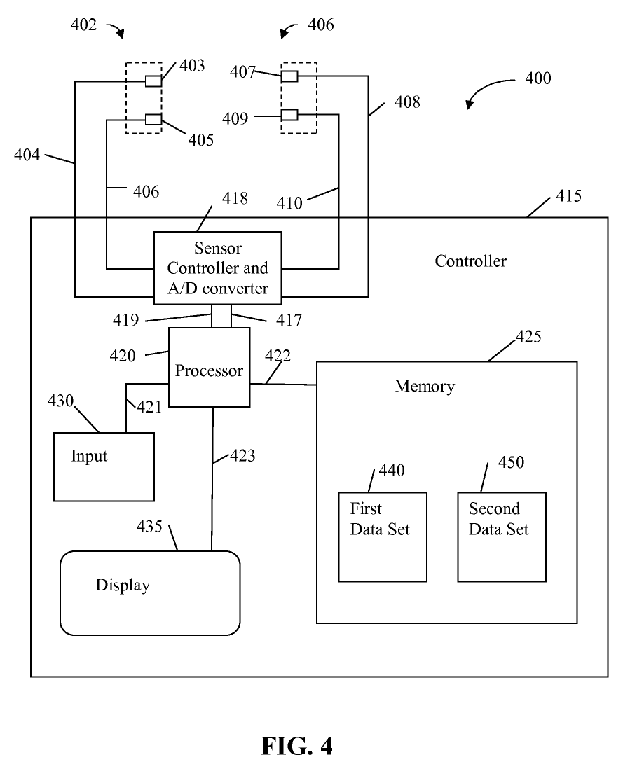

FIG. 4 illustrates a simplified block diagram of the electrical components of a system 400 for determining moisture content in a bale of hay in accordance with one embodiment of the present invention. The exemplary embodiment of system 400 includes a controller 415 that has a processor 420 in circuit communication with an input 430, a display 435, memory 425 and a sensor controller 418. Sensor controller 418 includes an analog to digital converter, which is in circuit communication with a pair of sensors 402, 406. There are also any of a number of switching components (not shown), such as, for example, relays or transistors, for controlling which electrodes are being used at various times to obtain measurements. First data set 440 and second data set 450 are stored in memory 425. Additional data sets may be used for specific applications, and optionally the data sets may be stored in a single database.

The components illustrated in FIG. 4 may be arranged or grouped differently depending on the design parameters. For example, the analog to digital converter of sensor controller 418 may be internal to processor 420. Another example is memory 425 may be internal RAM, external RAM, an internal or external EEPROM, or any other type of internal or external memory. The particular configurations illustrated herein are not meant to be limiting in any way.

First data set 440 may be a database that correlates a digital value of a measurement (taken between a first pair of electrodes) to a moisture content of a bale of hay. First data set 440 may be developed based on, or derived from, a series of test measurements taken from a similarly situated first pair of electrodes, for example, a pair of electrodes in close proximity with one another and in contact with the same edge of a hay bale. Similarly second data set 450 may be a database that correlates a digital value (of a measurement taken between a second pair of electrodes) to a moisture content of a bale of hay. Second data set 450 may be based on, or derived from, a series of test measurements taken from a second pair of electrodes. The second pair of electrodes may, for example, contact opposite edges of a hay bale. Other electrode positions may be used and the description herein of having electrodes adjacent to one another or on opposite edges of a hay bale is not required. However, the data sets are preferable compiled using test data from similarly situated electrodes.

Optionally, formulas for the moisture curves may be used instead of data sets. Formulas for the moisture curve may be derived, for example, by plotting the data set and calculating, for example, a second order polynomial, a fourth order polynomial, or other similar type of equation. Accordingly, it should be understood that in the descriptions of the embodiments herein, when a “data set” is described, it may include use of a moisture curve formula.

In operation, to determine moisture content of a hay bale, the processor 420 initiates a request through line 417 to the sensor controller 418 to obtain a first measurement across the electrodes 403, 405 of the first sensor 402. A signal, such as, for example, a 5 volt signal is transmitted to electrode 403 through cable 404. When a hay bale (not shown) is in contact with both electrodes 403 and 405, a portion of the signal transmitted to electrode 403 is received by electrode 405 and communicated to sensor controller 418. The higher the moisture content the more conductive the hay bale is and the lower the voltage drop across sensor 402 through cable 406. The signal is converted from an analog signal to a digital signal and communicated to the processor 420 through line 419. The processor 420 compares the value of the signal to a first data set 440 stored in memory 425 and determines a first moisture content measurement of the bale of hay and stores that value in memory 425. Optionally, the value of the signal may be applied to a first moisture curve formula to determine a moisture count. This step may be repeated any number of times and averaged to determine a first moisture content measurement.

Processor 420 may issue a similar request to take a measurement between electrodes 407 and 409. A signal is transmitted through cable 408 to electrode 407 and conducted through the hay bale to electrode 409 and communicated through cable 410 back to sensor controller 418 and converted to a digital signal. The digital signal is communicated to the processor 420 and the signal is compared to the first data set 440 to determine a second moisture content measurement of the hay bale. Optionally, the value of the signal may be applied to the first moisture curve formula to determine a moisture count. Again this step may be repeated any number of time and averaged to determine a second moisture content. The second moisture content measurement is stored in memory 425.

Then processor 420 may issue a request to take a measurement between electrode 403 and electrode 407. Sensor controller 418 transmits a signal through cable 404 to electrode 403. The signal is transmitted from electrode 403 through the hay bale to electrode 407 where the signal is transmitted back to the sensor controller 418 and converted to a digital signal and a value is communicated to the processor 420. Processor 420 compares the value to the second data set 450 to determine a third moisture content measurement of the hay bale. Optionally, the value of the signal may be applied to a second moisture curve formula to determine a moisture count. Again this step may be repeated any number of times and averaged to determine a third moisture content. The third moisture content measurement is stored in memory 425.

Processor 420 compares the first, second and third moisture content measurements and provides a final moisture content output to display 435 through line 423. The final moisture content is a function of at least two of the first, second and third moisture content measurements, and preferably a function of all three moisture content measurements.

In one embodiment, the user may select a hay bale width. A dataset or moisture curve formula for each of the different widths of hay bale may be provided and used in the determination of the moisture content. Optionally, a scaling factor may be used to scale a data set or moisture curve formula instead of providing a separate data set or moisture curve formula based on a variety of widths. Similarly, in one embodiment the user may select a hay bale density. A separate data set or moisture curve may be provided and used in the determination of the moisture content based on the density. Preferably, however, a scale factor is used to scale a data set or moisture curve formula based on the density. Thus, the final moisture content may also be a function of the width of the hay bale, and/or the density of the hay bale.

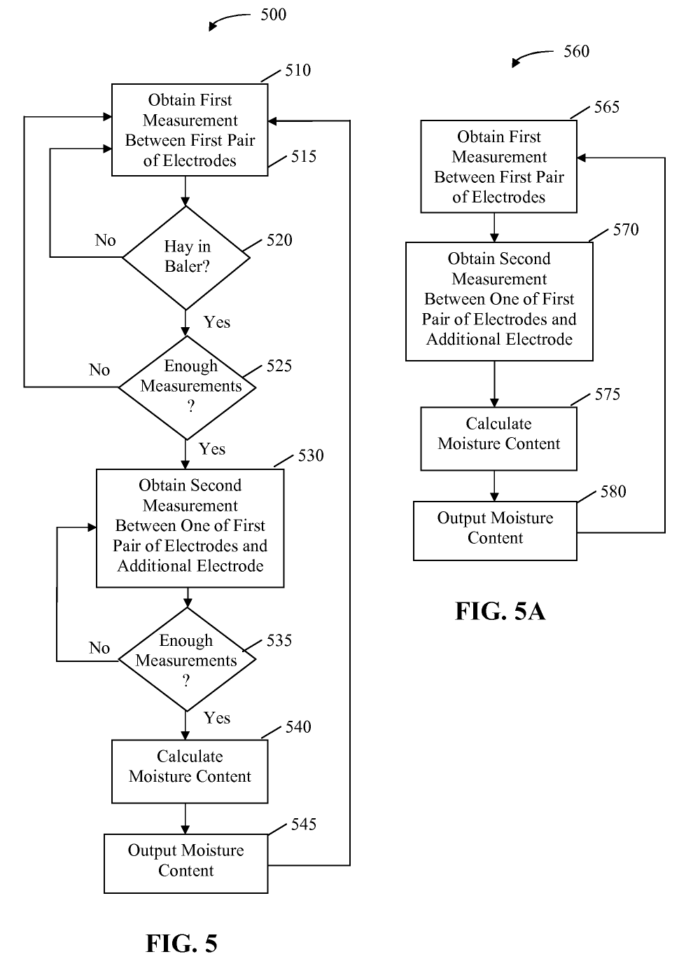

FIG. 5 is an exemplary flow chart 500 of a logic diagram of an embodiment for determining the moisture content of a bale of hay. A measurement is made between a first pair of electrodes at block 510. At block 520 a determination is made whether there is hay in the baler. The determination may be made based on, for example, whether the signal between the first pair of electrodes below or above a set threshold. If no hay is detected, the logic returns to block 510 and another measurement is made. If hay is detected at block 520 a determination of whether enough measurements have been taken is made at block 525. The number of measurements may be based on, for example, a set number of measurements that are to be averaged together, or based on obtaining a set number of measurements that are within a selected deviation of one another. If enough measurements have not been taken, the logic loops to block 510. If enough measurements have been taken, a second measurement between one of the first pair of electrodes and an additional electrode is taken at block 530. At block 535 a determination is made of whether enough measurements have been taken for the second measurement. If not enough measurements have been taken, the logic loops back to block 530 and additional measurements are taken. If enough measurements have been taken, the moisture content of the bale of hay is calculated at block 540 as a function of the first and second measurements and is output at block 545.

FIG. 5A is another exemplary flow chart 560 of another logic diagram of an embodiment for determining the moisture content of a bale of hay. A measurement is made between a first pair of electrodes at block 565. A second measurement between one of the first pair of electrodes and an additional electrode is taken at block 570. Optionally, additional measurements between different electrodes may be taken. The moisture content of the bale of hay is calculated at block 575 as a function of at least the first and second measurements and is output at block 580.

Many farmers have multiple types of hay balers. For example, a farmer may have a small square hay baler for harvesting hay to store in a hay loft, or to sell to individuals who own a few horses. The small square bales typically weigh between about 50 to 75 pounds. The same farmer may also have a round hay baler for harvesting hay for his herd of cattle. The round bales may weigh 1000 pounds. In accordance with one embodiment, the farmer need only install electrodes and wiring in each of his hay balers, and he can use a single controller for all of the hay balers.

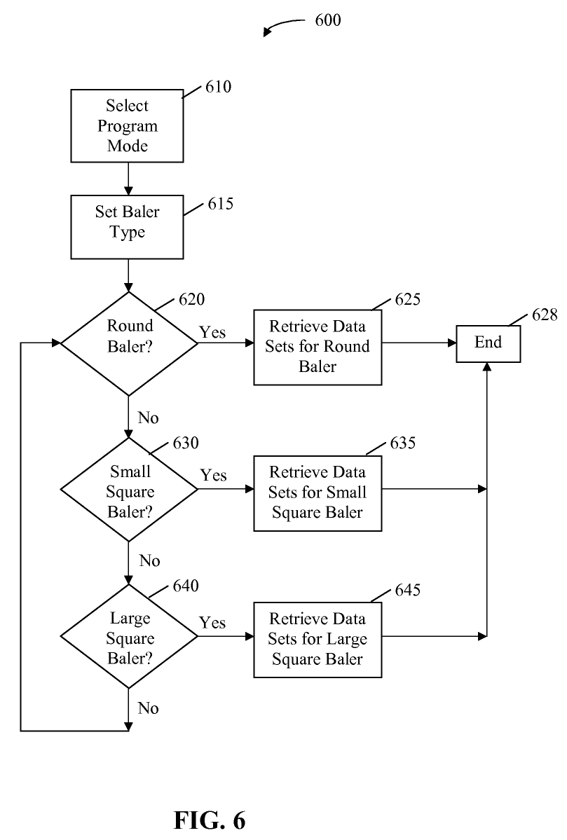

FIG. 6 is an exemplary flow chart 600 of a logic diagram in accordance with one embodiment of a method for using a single controller to determine the moisture content of different types of hay bales. At block 610 the program mode is selected. The user scrolls to the menu for setting the baler type at 615. At block 620 a determination is made whether a round baler is connected to the tractor. If it is, data sets for a round baler are retrieved 625 from memory for use in correlating the measurement from the sensors into a moisture content for a round bale of hay. At block 630 a determination is made whether a small square baler is connected to the tractor. If it is, data sets for a small square baler are retrieved 635 from memory for use in correlating the measurement from the sensors into a moisture content for a small square bale of hay. At block 640 a determination is made whether a large square baler is connected to the tractor. If it is, data sets for a large square baler are retrieved 645 from memory for use in correlating the measurement from the sensors into a moisture content for a large square bale of hay. Once the appropriate data sets are retrieved from memory, the logic ends at block 628.

The order in which the process flows herein have been described is not critical and can be rearranged while still accomplishing the same or similar results. Indeed, the process flows described herein may be rearranged, consolidated, and/or re-organized in their implementation as warranted or desired.

While various inventive aspects, concepts and features of the inventions may be described and illustrated herein as embodied in combination in the exemplary embodiments, these various aspects, concepts and features may be used in many alternative embodiments, either individually or in various combinations and sub-combinations thereof. Unless expressly excluded herein all such combinations and sub-combinations are intended to be within the scope of the present inventions. Still further, while various alternative embodiments as to the various aspects, concepts and features of the inventions—such as alternative materials, structures, configurations, methods, circuits, devices and components, software, hardware, control logic, alternatives as to form, fit and function, and so on—may be described herein, such descriptions are not intended to be a complete or exhaustive list of available alternative embodiments, whether presently known or later developed. Those skilled in the art may readily adopt one or more of the inventive aspects, concepts or features into additional embodiments and uses within the scope of the present inventions even if such embodiments are not expressly disclosed herein. Additionally, even though some features, concepts or aspects of the inventions may be described herein as being a preferred arrangement or method, such description is not intended to suggest that such feature is required or necessary unless expressly so stated. Still further, exemplary or representative values and ranges may be included to assist in understanding the present disclosure; however, such values and ranges are not to be construed in a limiting sense and are intended to be critical values or ranges only if so expressly stated. Moreover, while various aspects, features and concepts may be expressly identified herein as being inventive or forming part of an invention, such identification is not intended to be exclusive, but rather there may be inventive aspects, concepts and features that are fully described herein without being expressly identified as such or as part of a specific invention. Descriptions of exemplary methods or processes are not limited to inclusion of all steps as being required in all cases, nor is the order that the steps are presented to be construed as required or necessary unless expressly so stated.

We claim:

1. A system for measuring the moisture content in a bale of hay comprising:
a first pair of electrodes configured to mount in a first position in a bale chamber;
at least one additional electrode configured to mount in a second position in the bale chamber;
a controller having circuitry to obtain a first measurement between the first pair of electrodes while the electrodes are in contact with a bale of hay;
the controller having circuitry to obtain a second measurement between at least one of the first pair of electrodes and the at least one additional electrode while the electrodes are in contact with the bale of hay;
the controller having circuitry to determine a moisture content as a function of the first and second measurements and to output a signal indicative of the moisture content of the bale of hay; and
the controller having at least one of a display for displaying the moisture content and circuitry for communicating the signal indicative of the moisture content to a receiver located on a tractor or the hay baler.

2. The system of claim 1 wherein the at least one additional electrode comprises a second pair of electrodes and the controller includes circuitry to take a third reading between the second pair of electrodes and determine a moisture content of the bale of hay as a function of the first, second and third measurements.

3. The system of claim 1 wherein the first pair of electrodes is positioned on a first side of the bale chamber and wherein the at least one additional electrode is positioned on a second side of the bale chamber.

4. The system of claim 1 wherein the controller further comprises a first look-up table having a first stored data set that may be used to correlate the first measurement to a first moisture content, and a second look-up table having a second stored data set that may be used to correlate the second measurement to a second moisture content.

5. The system of claim 1 wherein the controller further comprises a first moisture curve formula that may be used to correlate the first measurement to a first moisture content, and a second moisture curve formula that may be used to correlate the second measurement to a second moisture content.

6. The system of claim 1 wherein the circuitry for communicating the signal indicative of the moisture content is an ISO CAN bus.

7. The system of claim 1 wherein the circuitry for communicating the signal indicative of the moisture content comprises a wireless transmitter.

8. The system of claim 1 wherein the controller has both a display for displaying the moisture content and circuitry for communicating the signal indicative of the moisture content to a receiver located on a tractor or the hay baler.

9. The system of claim 1 wherein the controller further comprises an input for selecting the type of hay baler and the controller includes data sets or moisture curve formulas for each type of hay baler that may be used.

10. The system of claim 9 wherein the controller further comprises an input for selecting a width of a hay bale to be bailed by the bailer.

11. The system of 1 wherein the controller further comprises an input for selecting a density of a hay bale to be bailed by the bailer.

12. A method for determining the moisture content of a bale of hay comprising:
taking a first measurement between a first pair of electrodes while the electrodes are in contact with a side of a bale of hay;
taking a second measurement between at least one of the first pair of electrodes and at least one additional electrode, wherein the first pair of electrodes and the at least one additional electrode are positioned so that a signal passing between them travels through at least substantially the width of the bale of hay;
determining the moisture content of the bale of hay as a function of the first measurement and the second measurement; and
providing a moisture content output to a display.

13. The method of claim 12 wherein the at least one additional electrode comprises two electrodes forming a second pair of electrodes; and the method further comprises taking a third measurement between the second pair of electrodes while the electrodes are in contact with a side of a bale of hay, and determining the moisture content of the bale of hay as a function of the first measurement, the second measurement and the third measurement.

14. The method of claim 13 wherein the moisture content of the bale of hay is determined by averaging at least two of the first measurement, the second measurement and the third measurement.

15. The method of claim 13 further comprising receiving an input for receiving a density of the bale of hay and wherein determining the moisture content of the bale of hay is also a function of the density of the bale of hay.

16. A method for using a moisture testing device for a bale of hay comprising:
providing a moisture testing device having an input for selecting a type of hay baler to be used;
providing a display to display the available types of hay balers;
providing a data set or moisture curve formula for each type of hay baler that may be selected; and
providing an option for selecting a type of hay baler to be used that cause the data set or moisture curve formula for the selected type of hay baler to be used in determining the moisture content of a bale of hay.

17. The method of claim 16 wherein the types of hay baler include at least two of a round hay baler, a small square hay baler and a large square baler.

18. The method of claim 16 further comprising taking a first measurement between a first pair of electrodes while the electrodes are in contact with a bale of hay, and providing an output indicative of the moisture content of the bale of hay as a function of the first measurement and the data set or moisture curve formula for the selected type of hay bale.

19. The method of claim 18 further comprising taking a second measurement between at least one of the first pair of electrodes and another electrode while the electrodes are in contact with a bale of hay, and providing an output indicative of the moisture content of the bale of hay as a function of the first measurement, the second measurement and the data set or moisture curve formula for the selected type of hay bale.

20. The method for use of a moisture testing device for a bale of hay of claim 18 further comprising taking a second measurement between at least one of the first pair of electrodes and another electrode while the electrodes are in contact with a bale of hay, and providing an output indicative of the moisture content of the bale of hay as a function of the first measurement, the second measurement and the data set or moisture curve formula for the selected type of hay bale.

21. A system for measuring the moisture content in a bale of hay comprising:
a first pair of electrodes configured to mount in a bale chamber;
a second pair of electrodes configured to mount in the bale chamber;
a controller having circuitry to obtain a first measurement between the first pair of electrodes while the electrodes are in contact with a bale of hay;
the controller having circuitry to obtain a second measurement between the second pair of electrodes while the electrodes are in contact with the bale of hay;
the controller having circuitry to determine a moisture content as a function of the first and second measurements and to output a signal indicative of the moisture content of the bale of hay; and
the controller having at least one of a display for displaying the moisture content and circuitry for communicating the signal indicative of the moisture content to a receiver located on a tractor or the hay baler.
